(19) United States
(12) Patent Application Publication
(10) Pub. No.: US 2026/0194560 A1
(43) Pub. Date: Jul. 9, 2026

(54) CONTROL METHOD FOR IMPROVING PROBE GRINDING EFFICIENCY

(71) Applicant: GLTTEK CO., LTD, HSINCHU CITY (TW)

(72) Inventors: CHIUNG-NAN CHEN, HSINCHU CITY (TW); PEI HUA CHANG, HSINCHU CITY (TW); HSIEN CHI SU, HSINCHU CITY (TW)

(21) Appl. No.: 19/012,253

(22) Filed: Jan. 7, 2025

(51) Int. Cl. G01R 3/00; G01R 1/073

(52) U.S. Cl. CPC G01R 3/00; G01R 1/07342

(57) ABSTRACT

A control method for improving probe grinding efficiency is executed by a processing unit of a probe grinding device, the method comprising: receiving a raw data, capturing an initial value, a section maximum value, and an end value of each grinding data section, computing a value increment, a value decrement, and a variation ratio of each grinding data section, and determining whether a grinding state of a probe card is consistent with a feeding condition or a stopping condition according to the value increment, the value decrement, and the variation ratio of each grinding data section; when the grinding state of the probe card is consistent with the feeding condition, the processing unit controls a grinding base to feed a grinding unit toward the probe card; when the grinding state of the probe card is consistent with the stopping condition, the processing unit controls the grinding base to stop grinding.

### BACKGROUND OF THE INVENTION

### 1. Field of the Invention

The present invention relates to a control method, especially a control method for improving probe grinding efficiency.

### 2. Description of the Related Art

In a field of semiconductor manufacturing, a wafer is tested through a probe card to confirm whether functions of each die on the wafer are normal. Only the dies that have been tested and have normal functions will proceed to subsequent packaging processes to save cost from packaging defect dies. The probe card comprises multiple probes, and each probe is adapted to contact the die on the wafer in a testing process. To ensure that multiple probes can contact each die on the wafer evenly (to avoid a situation that some probes have over-contacted the dies but some probes have not contacted the dies yet), the multiple probes of the probe card usually undergo processes such as grinding, preheating, etc. to make lengths of the multiple probes consistent.

A conventional probe grinding device is adapted to grind the multiple probes of the probe card. When the probe card is placed in the conventional probe grinding device, the probe grinding device can control a grinding base to contact the multiple probes for grinding. Since the lengths of the multiple probes before grinding are not consistent, the probe grinding device will control the grinding base to feed a length of a grinding unit every preset time duration to grind more from the multiple probes. For example, the probe card comprises multiple first probes and multiple second probes, and lengths of the multiple first probes are greater than lengths of the multiple second probes. In a first grinding stage, the grinding base grinds the multiple first probes, the lengths of the multiple first probes will gradually become shorter. At the end of the first grinding stage, the probe grinding device controls the grinding base to feed a length of a grinding unit. Therefore, the grinding base can grind the multiple first probes and the multiple second probes at the same time in a second grinding stage.

However, the multiple first probes may be completely ground at a time point in the first grinding stage, so that the grinding base is in an idling state from the time point to the end of the first grinding state. As a result, the probe grinding device has a poor grinding efficiency and consume unnecessary operating power. In addition, the lengths of the multiple first probes may not become shorter as expected after the first and second grinding stages. If the probe grinding device continues to control the grinding base to feed the grinding unit, the grinding efficiency of the probes will not be improved as expected, even causing the multiple first probes to fracture and increasing processing cost.

### SUMMARY OF THE INVENTION

A conventional probe grinding device lacks controlling ways for grinding efficiency, resulting in problems as described in the prior art. In view of this, the present invention provides a control method for improving probe grinding efficiency, executed by a processing unit of a probe grinding device and comprising:
receiving a raw data of a driving module, wherein the raw data includes multiple grinding data sections which are continuous;
capturing an initial value, a section maximum value, and an end value of each grinding data section;
computing a value increment, a value decrement, and a variation ratio of each grinding data section according to the initial value, the section maximum value, and the end value of each grinding data section; and
determining whether a grinding state of a probe card is consistent with a feeding condition or a stopping condition according to the value increment, the value decrement, and the variation ratio of each grinding data section;
wherein when the processing unit determines that the grinding state of the probe card is consistent with the feeding condition, the processing unit controls a grinding base to feed a grinding unit toward the probe card;
when the processing unit determines that the grinding state of the probe card is consistent with the stopping condition, the processing unit controls the grinding base to stop grinding.

The present invention enables the processing unit to determine grinding efficiencies of the probe grinding device and execute control processes corresponding to improvement of the grinding efficiencies. For example, the present invention reduces occurrences of idling of the grinding base, continuing to control the grinding base to feed despite poor grinding efficiency, etc. as mentioned in the prior art, thereby shortening the required time for the entire grinding process and improving the grinding efficiencies of the probes.

### BRIEF DESCRIPTION OF THE DRAWINGS

FIG. 1 is a schematic diagram of a probe grinding device executing a control method for improving probe grinding efficiency of the present invention;

FIG. 2 is a circuit block diagram of the probe grinding device executing the control method for improving probe grinding efficiency of the present invention;

FIG. 3 is a flow chart of the probe grinding device executing the control method for improving probe grinding efficiency of the present invention;

FIG. 4 is a schematic diagram of a raw data of a driving module in the probe grinding device;

FIG. 5 is a schematic diagram of multiple grinding sections of the raw data;

FIG. 6 is a histogram of a variation ratio corresponding to each grinding data section;

FIG. 7 is a schematic diagram of multiple grinding sections, wherein the multiple grinding sections include a stable section; and

FIG. 8 is a schematic diagram of relationships of a value increment corresponding to each grinding data section.

### DETAILED DESCRIPTION OF THE INVENTION

In order to understand the technical characteristics and practical effects of the prevent invention in detail, and accomplish them according to the content of the present invention, the detailed description is as follows with the embodiments shown in the figures.

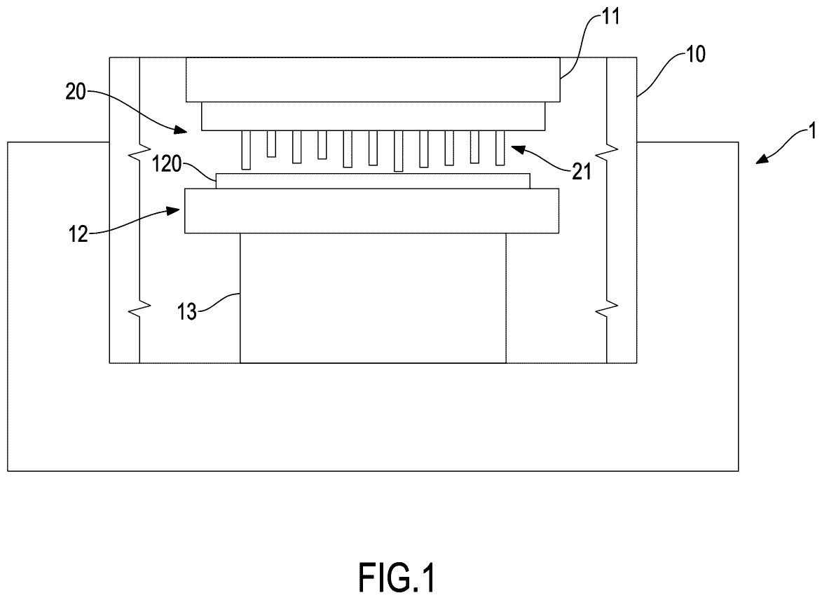

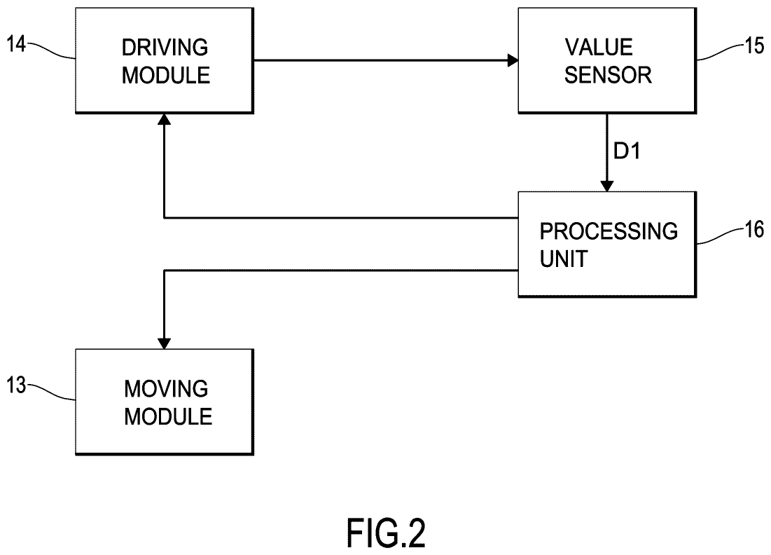

Referring to FIGS. 1 and 2, a control method for improving probe grinding efficiency of the present invention is executed by a probe grinding device 1. The probe grinding device 1 is installed with a probe card 20 inside, and the probe card 20 has multiple probes 21. In particular, the probe grinding device 1 comprises a grinding cavity 10, a fixing base 11, a grinding base 12, a moving module 13, a driving module 14, a value sensor 15, and a processing unit 16, wherein the fixing base 11, the grinding base 12, and the moving module 13 are mounted in the grinding cavity 10. The fixing base 11 is mounted on a top side of the grinding cavity 10 to fix the probe card 20. The grinding base 12 is mounted under the fixing base 11 and the probe card 20. Needle tips of the multiple probes 21 of the probe card 20 jointly face the grinding base 12. Moreover, a grinding part 120 is mounted on the grinding base 12. For example, the grinding part 120 can be a sandpaper, a grinding wheel, etc. The present invention is not limited to the foregoing examples.

The moving module 13 can drive the grinding base 12 to move linearly (upward and downward), so that the grinding part 120 may approach the probe card 20 or move away from the probe card 20. When the grinding base 12 contacts the multiple probes 21 of the probe card 20, the driving module 14 can drive the grinding base 12 to rotate. The grinding part 120 rotates with the grinding base 12 to grind the multiple probes 21. For example, the driving module 14 includes a motor, a motor reducer, a gear set, etc. The principle of the moving module 13 to drive the grinding base 12 to move and the principle of the driving module 14 to drive the grinding base 12 to rotate are not technical focus of the present invention and will not be described in detail.

The value sensor 15 is electrically connected with the driving module 14 and the processing unit 16. The value sensor 15 is adapted to sense an operating value of the driving module 14. For example, the operating value can be a voltage value, a current value, a torque value, etc. of the motor in the driving module 14. The present invention is not limited to the foregoing examples. The processing unit 16 is electrically connected with the driving module 14 and the moving module 13 to respectively control an operating state of the driving module 14 and the moving module 13. Thereby, the processing unit 16 controls a rotation speed of the grinding base 12 and controls the grinding base 12 to approach or move away from the multiple probes 21. For example, the processing unit 16 is a programmable logic controller (PLC), a computer to execute computer numerical control (CNC), etc.

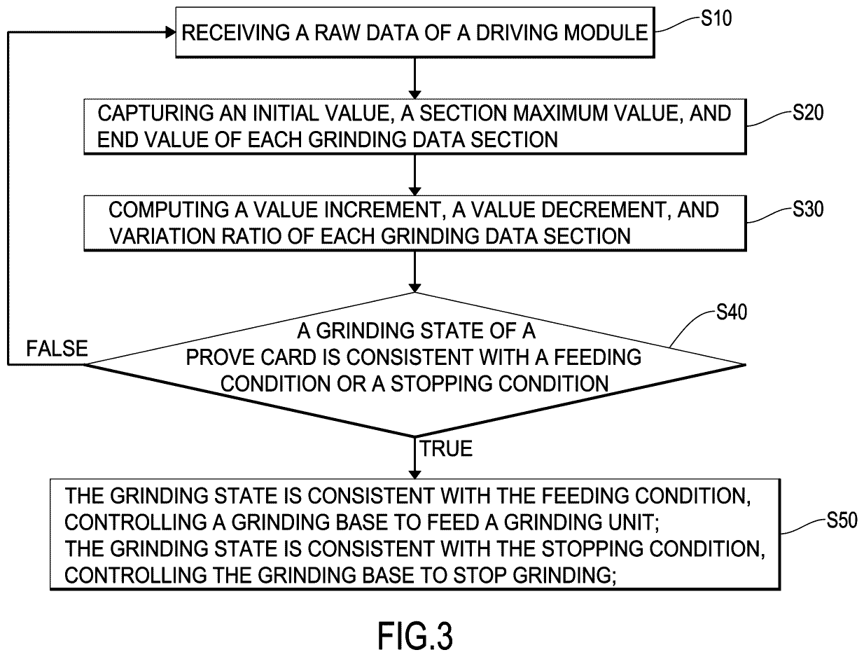

The control method of improving probe grinding efficiency of the present invention is executed by the processing unit 16 in the probe grinding device 1. Referring to FIG. 3, the control method of the present invention includes the following steps.

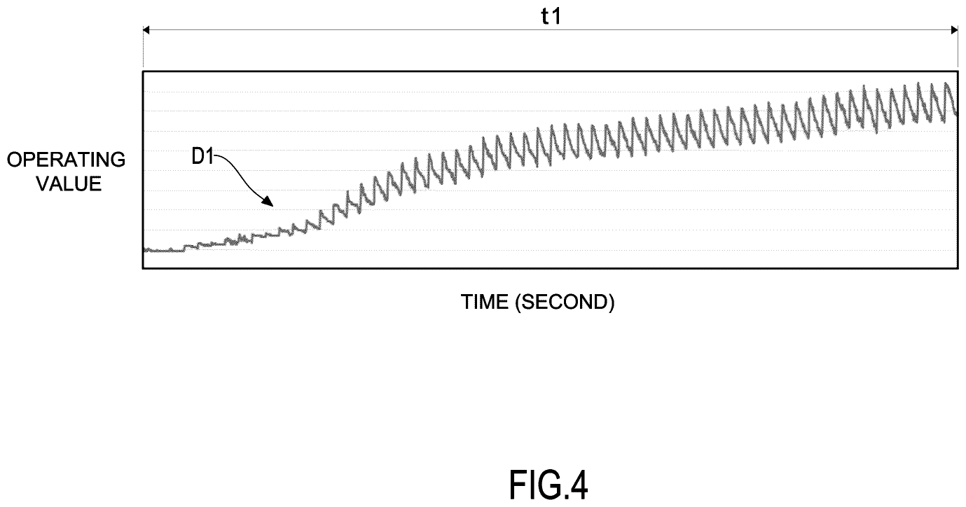

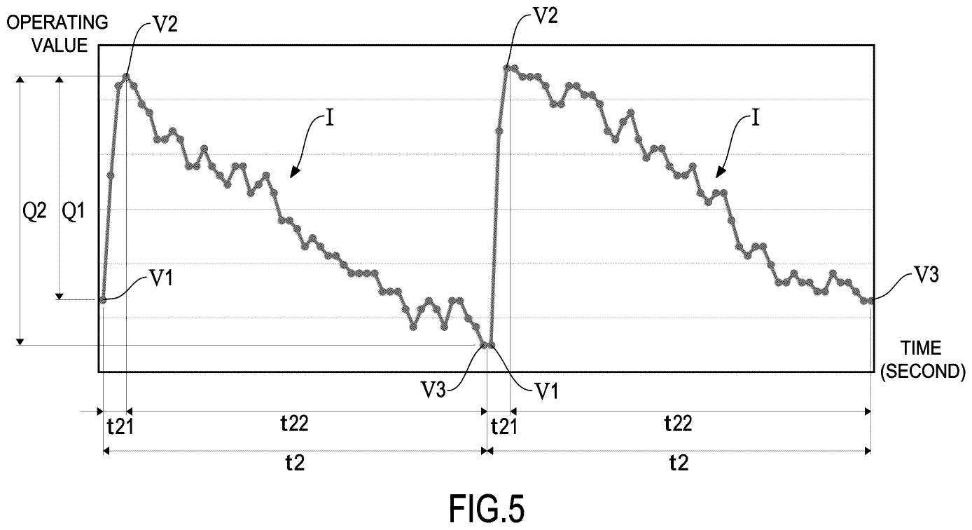

Step S10: the processing unit 16 receives a raw data D1 of the driving module 14 as shown in FIG. 4. As mentioned above, the raw data D1 is the operating value of the driving module 14. That is, the operating value as shown in FIG. 4 can be the voltage value, the current value, or the torque value of the motor in the driving module 14. The following description will take the raw data D1 of the torque value (the motor in the driving module 14 is operating) as an example. Referring to FIGS. 4 and 5 (the operating value in FIG. 5 is taken from FIG. 4), the raw data D1 includes multiple grinding data sections I, and the multiple grinding data sections I are continuous. Specifically, the processing unit 16 is preset with a feeding cycle. A duration of entire process of the probe grinding device 1 grinding the multiple probes 21 corresponds to a total grinding duration t1 in FIG. 4. The processing unit 16 starts timing when the process of grinding the multiple probes 21 starts. When the processing unit 16 determines that the feeding cycle timing is reached, the processing unit 16 controls the moving module 13 to feed a grinding unit (a length unit). For example, the feeding cycle is 50 seconds. After the processing unit 16 controls the moving module 13 to feed the grinding unit at a first time point, the processing unit 16 will subsequently control the moving module 13 at a second time point (50 seconds later) to feed the grinding unit, wherein a duration of the first time point and the second time point is a grinding duration t2. The grinding duration t2 includes a feeding duration t21 during which the moving module 13 feeds the grinding unit and a grinding duration t22 during which the grinding module 12 grinds the probe card 20.

In other words, the processing unit 16 controls the moving module 13 to feed the grinding unit (length unit) during every grinding duration t2, so that the moving module 13 drives the grinding base 12 to move toward the probe card 20. That is, the process of grinding the multiple probes 21 includes multiple grinding stages, and the grinding duration t2 is a duration of every grinding stage. For example, referring to FIG. 5, the grinding data section I corresponding to a grinding stage includes an initial value V1, a section maximum value V2 and an end value V3. The time corresponding to the grinding data section I between the initial value V1 and the section maximum value V2 is defined as the feeding duration t21, and the time corresponding to the grinding data section I between the section maximum value V2 and the end value V3 is defined as the grinding duration t22.

At the end of each grinding stage, the processing unit 16 controls the grinding base 12 to move the grinding unit toward the probe card 20. In the process of the probe grinding device 1 grinding the multiple probes 21 (the total grinding duration I as shown in FIG. 4), the value sensor 15 continues to sense the operating value of the driving module 14 to generate the raw data D1. The processing unit 16 is electrically connected with the value sensor 15 to receive the raw data D1, wherein the multiple grinding data sections I respectively correspond to the multiple grinding stages.

The operating value of the driving module 14 will change according to a number of the probes that contact the grinding base 12. When the grinding base 12 contacts more probes 21, the operating value (value of the raw data D1) sensed by the value sensor 15 will be greater. When the grinding base 12 contacts fewer probes 21, the operating value (value of the raw data D1) sensed by the value sensor 15 will be smaller. Since the multiple probes 21 have larger length differences before the multiple probes 21 are ground, the grinding base 12 only contacts longer probes 21 among the multiple probes 21. That is, the grinding base 12 contacts fewer probes 21, and a value of the raw data D1 sensed by the value sensor 15 is smaller. The lengths of the multiple probes 21 will tend to be consistent when the process of grinding the multiple probes 21 is nearly completed, so that the grinding base contacts more probes 21, and the value of the raw data D1 sensed by the value sensor 15 is greater.

Step S20: referring to FIG. 5, the processing unit 16 captures the initial value V1, the section maximum value V2, and the end value V3. In particular, in the beginning of each grinding stage, the grinding base 12 only slightly contacts the longer probes 21 among the multiple probes 21. At this time, the value of the raw data D1 of the driving module 14 sensed by the value sensor 15 is a first value. When the grinding base 12 starts to move the grinding unit (starts the feeding duration t21), a force of the grinding base 12 contacts the longer probes 21 will increase. A resistance force received by the driving module 14 will increase accordingly, and the operating value will increase rapidly. At this time, the value of the raw data D1 of the driving module 14 sensed by the value sensor 15 is a second value. When the feeding duration t21 ends, the grinding duration t22 will immediately enter. As the grinding base 12 grinds the multiple probes 21, the length of the longer probes 21 among the multiple probes 21 will gradually become shorter. As the length of the longer probes 21 becomes shorter, the force of the grinding base 12 contacting the longer probes 21 will decrease. The resistance force received by the driving module 14 will decrease accordingly, and the operating value will decrease. At the end of each grinding stage (the end of each grinding duration t2), the value of the raw data D1 of the driving module 14 sensed by the value sensor 15 is a third value, wherein the third value can be the first value of next grinding stage. Subsequently, the processing unit 16 controls the grinding base to feed the grinding unit to enter the next grinding stage. The multiple grinding stages are repeated in this manner until the multiple probes 21 are completely ground.

In each grinding stage, the grinding base 12 rotates continuously. That is, in the feeding duration t21, the multiple probes 21 are subjected to increasing contact force and are ground at the same time. However, for the driving module 14, an increasing amount of the resistance force is greater than a decreasing amount of the resistance force, so that the operating value of the driving module 14 increases upward from the first value.

For example, when a first grinding stage is just finished and a subsequent second grinding stage begins, the processing unit 16 captures a current value of the raw data D1 (the first value) as the initial value V1 of the second grinding stage. Then, the processing unit 16 controls the moving module 13 to let the grinding base 12 start feeding the grinding unit (that is, the feeding duration begins). Since the force of the grinding base 12 contacts the longer probes 21 increases gradually, the value of the raw data D1 increases upward from the first value. When the processing unit 16 controls the moving module 13 to stop feeding, the processing unit 16 captures a current value of the raw data D1 (the second value) as the section maximum value V2 of the second grinding stage. When the processing unit 16 determines that the feeding cycle timing is reached (that is, the grinding duration ends), the processing unit 16 captures a current value of the raw data D1 (the third value) as the end value V3 of the second grinding value to end the second grinding stage, wherein the raw data D1 corresponding to the second grinding stage is a second grinding data section. The processing unit 16 captures the initial value V1, the section maximum value V2 and the end value V3 in each grinding data section I by the abovementioned method as a control judgment.

Step S30: the processing unit 16 respectively computes a value increment Q1, a value decrement Q2 and a variation ratio of each grinding data section I according to the initial value V1, the section maximum value V2, and the end value V3 of each grinding data section I. In particular, the value increment Q1 of each grinding data section I is the section maximum value V2 of each grinding data section I minus the initial value V1 of each grinding data section I. That is, Q1=V2−V1; the value decrement Q2 of each grinding data section I is the section maximum value V2 of each grinding data section I minus the end value V3 of each grinding data section I. That is, Q2=V2−V3; the variation ratio of each grinding data section I is the value decrement Q2 of each grinding data section I divided by the value increment Q1 of each grinding data section I. That is, the variation ratio=Q2/Q1, wherein the variation ratio of each grinding data section I can reflect a grinding efficiency of each grinding data section I.

Step S40: the processing unit 16 determines whether a grinding state of the probe card 20 is consistent with a feeding condition or a stopping condition according to the value increment Q1, the value decrement Q2 and the variation ratio of each grinding data section I. Specifically, the processing unit 16 of the probe grinding device 1 presets the feeding condition and the stopping condition. When the processing unit 16 determines that the grinding state of the probe card 20 is consistent with the feeding condition or the stopping condition, the processing unit 16 executes step S50 to control the grinding base 12 to feed the grinding unit toward the probe card or control the grinding base 12 to stop grinding. In particular, when the processing unit 16 determines that the grinding state of the probe card 20 is consistent with the feeding condition, the processing unit 16 controls the moving module 13 to drive the grinding base 12 to move the grinding unit toward the probe card 20. When the processing unit 16 determines that the grinding state of the probe card 20 is consistent with the stopping condition, the processing unit 16 controls the driving module 14 to stop operating to let the grinding base 12 stop operate and stop grinding the multiple probes 21. On the contrary, when the processing unit 16 determines that the grinding state of the probe card 20 is not consistent with the feeding condition and the stopping condition, the processing unit 16 does not perform any action to let the grinding base 12 grind the multiple probes 21 continuously.

In an embodiment of the present invention, the grinding state of the probe card 20 (the multiple probes 21) determined by the processing unit 16 may be one of the following.
1. The processing unit 16 determines whether the grinding efficiency of the grinding base 12 on the probe card 20 is reduced. That is, the grinding state is the grinding efficiency. A determining condition for the grinding state is a first stopping condition which is that the grinding efficiency decreases.
2. The processing unit 16 determines whether the probe card 20 has completed grinding in each grinding stage. That is, the grinding state is a trend of each grinding data section I. A determining condition for the grinding state is the feeding condition which is that each grinding data section I includes a stable section.
3. The processing unit 16 determines whether the probe card 20 has been fully ground. That is, the grinding state is the value increment Q1 of each grinding data section I. A determining condition for the grinding state is a second stopping condition which is that the value increment Q1 of each grinding data section I is greater than a fully-grinding threshold.

The first stopping condition, the feeding condition, and the second stopping condition are respectively described as follows.
1. The first stopping condition may be: among two adjacent grinding data sections I of the multiple grinding data sections I, the variation ratio of a latter grinding data section is smaller than the variation ratio of a former grinding data section. When the processing unit 16 determines that the variation ratio of the latter grinding data section is smaller than the variation ratio of the former grinding data section (is consistent with the first stopping condition), the processing unit 16 controls the grinding base 12 to stop grinding, wherein the variation ratio of a latter grinding data section is smaller than the variation ratio of a former grinding data section, which means the grinding efficiency of the grinding base 12 on the multiple probes 21 reduces. Reasons why the grinding efficiency of grinding base 12 reduces can be abrasion of the grinding part 120, poor adaptability between the grinding part 120 and the multiple probes 21, etc.

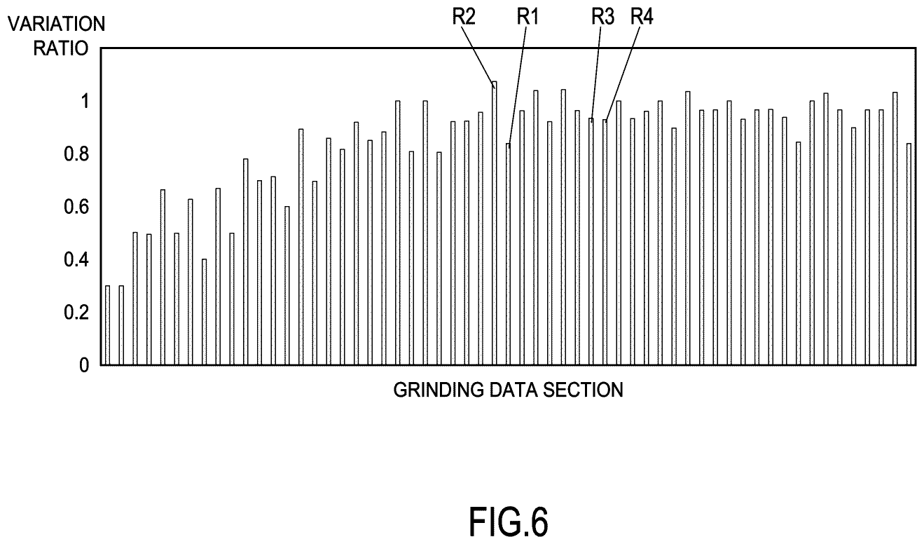

Referring to FIG. 6, FIG. 6 is a histogram of the variation ratio corresponding to each grinding data section I. For example, the variation ratio of one of the multiple grinding data sections I is a first variation ratio R1, and the variation ratio of the previous grinding data section is a second variation ratio R2. The value of the first variation ratio R1 is 0.82, and the value of the second variation ratio R2 is 1.14. The value of the first variation ratio R1 is smaller than the value of the second variation ratio R2 (is consistent with the first stopping condition), so that the processing unit 16 controls the grinding base 12 to stop grinding at the end of the grinding stage corresponding to the grinding data section I.

In an embodiment of the present invention, the processing unit 16 computes a first average variation ratio according to the variation ratios of at least two of the multiple grinding data sections I and computes a second average variation ratio according to the variation ratios of another at least two grinding data sections before the at least two of the multiple grinding data sections I. For example, referring to FIG. 6, the processing unit 16 computes the first average variation ratio according to a third variation ratio R3 and a fourth variation ratio R4, and a value of the first average variation ratio is 0.9. The processing unit 16 computes the second average variation ratio according to the first variation ratio R1 and the second variation ratio R2 before the third variation ratio R3 and the fourth variation ratio R4, and a value of the second average variation ratio is 0.98.

In the present embodiment, the first stopping condition may be: the value of the first average variation ratio is smaller than the value of the second average variation ratio. When the processing unit 16 determines that the value of the first average variation ratio is smaller than the value of the second average variation ratio, the processing unit 16 controls the grinding base 12 to stop grinding, wherein the value of the first average variation ratio is smaller than the value of the second average variation ratio, which means the grinding efficiency of the grinding base 12 on the multiple probes 21 reduces. Thereby, the processing unit 16 can determine the grinding efficiency of the grinding base 12 on the multiple probes 21 according to the operating value of the driving module 14. When the grinding efficiency is poor, the processing unit 16 controls the grinding base 12 to stop grinding the multiple probes 21 for the user to replace the grinding part 120 of the grinding base 12 to improve (recover) the grinding base 12 on the multiple probes 21.

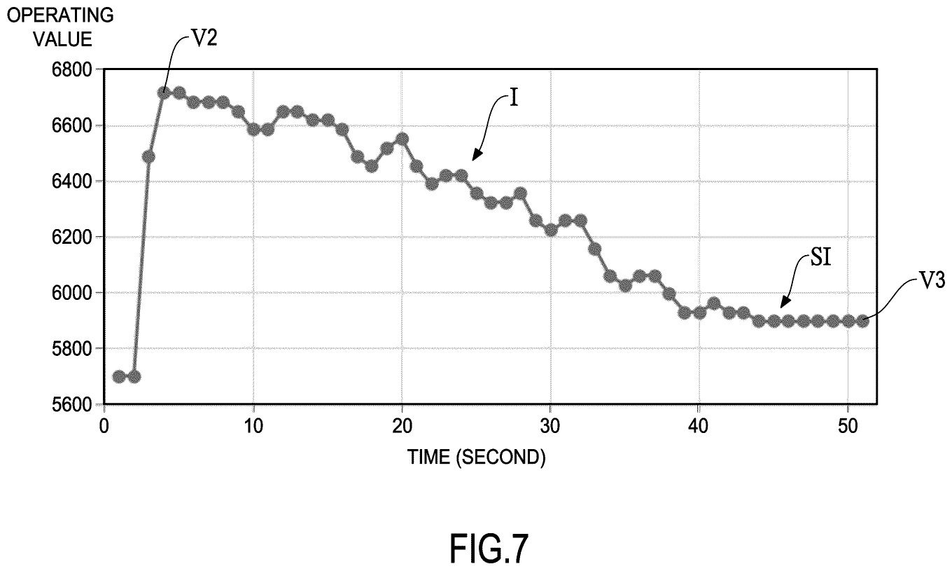

2. The feeding condition may be: a stable section SI as shown in FIG. 7 is included between the section maximum value V2 and the end value V3 in one of the multiple grinding sections I. When the processing unit 16 determines that the stable section SI is included between the section maximum value V2 and the end value V3 in one of the multiple grinding sections I, the processing unit 16 controls the grinding base 12 to feed the grinding unit toward the probe card 20.

Specifically, referring to FIG. 7 (the operating value in FIG. 7 is taken from FIG. 4), multiple consecutive grinding values (operating values) corresponding to multiple consecutive time points are included between the section maximum value V2 and the end value V3 in each grinding data section I. Multiple grinding value variations are included among the multiple consecutive grinding values. Each grinding value variation is a change between two consecutive and adjacent grinding values. The processing unit 16 continues to determine relationships between the multiple grinding value variations and a grinding value variation threshold. When the processing unit 16 determines at least two consecutive grinding value variations are less than or equal to the grinding value variation threshold, a section in the grinding data section I corresponds to the multiple grinding values corresponding to the at least two consecutive grinding value variations is the stable section I. That is, each grinding value variation in the stable section SI is less than or equal to the grinding value variation threshold.

In each grinding stage, the multiple probes 21 are ground by the grinding base 12 and gradually become shorter, so that the resistance force received by the driving module 14 is decreased accordingly and the operating value of the driving module 14 is decreased accordingly. Assuming the multiple probes 21 have completed grinding before a grinding stage is completed, the value of the raw data D1 of the driving module 14 sensed by the value sensor 15 will no longer change (that is, including the stable section SI). The processing unit 16 controls the grinding base 12 to feed the grinding unit toward the probe card 20 to enter the next grinding stage to prevent the grinding base 12 from being in an idling state without grinding any probes 21, thereby reducing unnecessary power consumption and shortening a required time for the entire grinding process.

3. The second stopping condition may be: the value increment Q1 of one of the multiple grinding data sections I is greater than or equal to a fully-grinding threshold, wherein the fully-grinding threshold is a product of a number of the multiple probes 21 and an average grinding value of the multiple probes 21. In particular, the processing unit 16 stores the number of the multiple probes 21 and the average grinding value of the multiple probes 21. For example, when setting various parameters of the probe grinding device 1, multiple probe cards 20 are used for operation testing. Whenever the probe grinding device 1 completes grinding a probe card 20, the processing unit 16 stores a current operating value (the raw data D1) of the driving module 16. Then, the processing unit 16 divides the current operating value by the number of the multiple probes 21 of the probe card 20 to obtain a grinding value of one of the multiple probes 21. After the probe grinding device 1 repeats operations several times, the processing unit 16 will store multiple grinding values. The processing unit 16 computes the average grinding value of the multiple probes 21 by statistics and stores the average grinding value for determination.

When the processing unit 16 determines the value increment Q1 of one of the multiple grinding data sections I is greater than or equal to the fully-grinding threshold, the processing unit 16 controls the grinding base 12 to stop grinding to finish the grinding process of the probe card 20. The value increment Q1 of one of the multiple grinding data sections I is greater than or equal to the fully-grinding threshold, which means the multiple probes 21 have been substantially ground to a desired length. That is, the multiple probes 21 have been completely ground, so that the grinding base contacts more probes 21 and generates a sufficient resistance force to the driving module 16.

In an embodiment of the present invention, the processing unit 16 counts an achieving times value. In particular, whenever the value increment Q1 of one of the multiple grinding data sections I is greater than or equal to the fully-grinding threshold, the processing unit 16 does not control the grinding base 12 to stop grinding and increases a value of a counter by one, wherein the value of the counter is the achieving times value. In other words, in the value increments Q1 corresponding to the multiple grinding data sections I, a number of the value increments Q1 that are greater than or equal to the fully-grinding threshold is defined as the achieving times value.

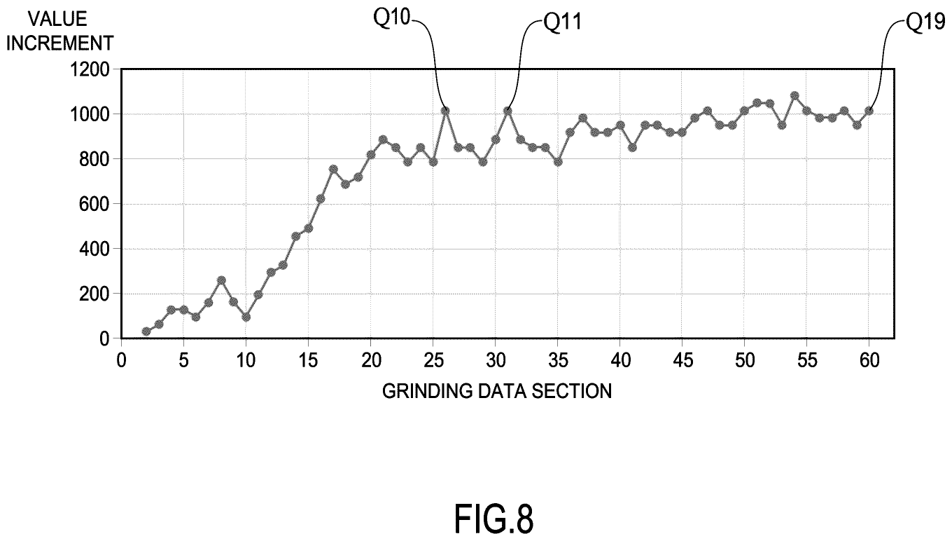

In the present embodiment, the second stopping condition may be: the achieving times value is greater than or equal to a setting times value. When the processing unit 16 determines that the achieving times value is greater than or equal to the setting times value, the processing unit 16 controls the grinding base 12 to stop grinding. For example, referring to FIG. 8, which is a diagram of relationships of the value increment Q1 corresponding to each grinding data section I. Assuming the fully-grinding threshold is 1000 (Newton-meter) and the setting time value stored by the processing unit 16 is 10 (times). In the value increments Q1 corresponding to the multiple grinding data sections I, a first one of the value increments Q1 that is greater than or equal to the fully-grinding threshold is a first value increment Q10, a second one of the value increments Q1 that is greater than or equal to the fully-grinding threshold is a second value increment Q11, and so on. When a tenth one of the value increments Q1 that is greater than or equal to the fully-grinding threshold (a tenth value increment Q19) is generated, the processing unit 16 controls the grinding base 12 to stop grinding at the end of the grinding stage corresponding to the tenth value increment Q19.

The control method for improving probe grinding efficiency of the present invention is executed by a processing unit 16 of a probe grinding device 1. The processing unit 16 receives a raw data D1 and captures an initial value V1, a section maximum value V2, and an end value V3 of each grinding data section I of the raw data D1 to compute a value increment Q1, a value decrement Q2, and a variation ratio of each grinding data section I. The processing unit 16 determines whether a grinding state of a probe card 20 is consistent with a feeding condition or a stopping condition according to the value increment Q1, the value decrement Q2 and the variation ratio of each grinding data section I. When the processing unit 16 determines that the grinding state of the probe card 20 is consistent with the feeding condition, the processing unit 16 controls a grinding base 12 to feed a grinding unit toward the probe card 20. When the processing unit 16 determines that the grinding state of the probe card 20 is consistent with the stopping condition, the processing unit 16 controls the grinding base 12 to stop grinding. The present invention enables the processing unit 16 to determine grinding efficiencies of the probe grinding device 1 and execute control processes corresponding to improving the grinding efficiencies. For example, the present invention reduces occurrences of idling of the grinding base 12, continuing to control the grinding base 12 to feed despite poor grinding efficiency, etc. as mentioned in the prior art, thereby shortening the required time for the entire grinding process and improving the grinding efficiencies of the probes 21.

The above only records the implementations or embodiments of the technical artifices adopted by the present invention to solve the problems, and is not configured to limit the claims of the present invention. That is, all equivalent changes and modifications that are consistent with the meaning of the claims of the present invention or made in accordance with the claims of the present invention are covered by the claims of the present invention.

What is claimed is:

1. A control method for improving probe grinding efficiency, executed by a processing unit of a probe grinding device and comprising:
receiving a raw data of a driving module, wherein the raw data includes multiple grinding data sections which are continuous;
capturing an initial value, a section maximum value, and an end value of each grinding data section;
computing a value increment, a value decrement, and a variation ratio of each grinding data section according to the initial value, the section maximum value, and the end value of each grinding data section; and
determining whether a grinding state of a probe card is consistent with a feeding condition or a stopping condition according to the value increment, the value decrement, and the variation ratio of each grinding data section;
wherein when the processing unit determines that the grinding state of the probe card is consistent with the feeding condition, the processing unit controls a grinding base to feed a grinding unit toward the probe card;
wherein when the processing unit determines that the grinding state of the probe card is consistent with the stopping condition, the processing unit controls the grinding base to stop grinding.

2. The control method for improving probe grinding efficiency as claimed in claim 1, wherein:
the value increment of each grinding data section is the section maximum value of each grinding data section minus the initial value of each grinding data section;
the value decrement of each grinding data section is the section maximum value of each grinding data section minus the end value of each grinding data section;
the variation ratio of each grinding data section is the value decrement of each grinding data section divided by the value increment of each grinding data section.

3. The control method for improving probe grinding efficiency as claimed in claim 1, wherein:
the stopping condition is that among two adjacent grinding data sections of the multiple grinding data sections, the variation ratio of a latter grinding data section is smaller than the variation ratio of a former grinding data section;
when the processing unit determines that the variation ratio of the latter grinding data section is smaller than the variation ratio of the former grinding data section among two adjacent grinding data sections, the processing unit controls the grinding base to stop grinding.

4. The control method for improving probe grinding efficiency as claimed in claim 1, wherein:
the processing unit computes a first average variation ratio according to the variation ratios of at least two of the multiple grinding data sections and computes a second average variation ratio according to the variation ratios of another at least two grinding data sections before the at least two of the multiple grinding data sections;
the stopping condition is that the first average variation ratio is smaller than the second average variation ratio;
when the processing unit determines that the first average variation ratio is smaller than the second average variation ratio, the processing unit controls the grinding base to stop grinding.

5. The control method for improving probe grinding efficiency as claimed in claim 1, wherein:
the feeding condition is that a stable section is included between the section maximum value and the end value in one of the multiple grinding data sections;
when the processing unit determines that the stable section is included between the section maximum value and the end value in one of the multiple grinding sections, the processing unit controls the grinding base to feed the grinding unit toward the probe card.

6. The control method for improving probe grinding efficiency as claimed in claim 5, wherein:
multiple consecutive grinding values are included between the section maximum value and the end value in each grinding data section; multiple grinding value variations are included among the multiple consecutive grinding values, and each grinding value variation is a change between two consecutive and adjacent grinding values;
each grinding value variation in the stable section is less than or equal to a grinding value variation threshold.

7. The control method for improving probe grinding efficiency as claimed in claim 1, wherein:
the stopping condition is that the value increment of one of the multiple grinding data sections is greater than or equal to a fully-grinding threshold;
when the processing unit determines that the value increment of one of the multiple grinding data sections is greater than or equal to the fully-grinding threshold, the processing unit controls the grinding base to stop grinding.

8. The control method for improving probe grinding efficiency as claimed in claim 7, wherein:
the probe card has multiple probes; the processing unit stores an average grinding value of the multiple probes, and the fully-grinding threshold is a product of a number of the multiple probes and the average grinding value.

9. The control method for improving probe grinding efficiency as claimed in claim 1, wherein:
in the value increments corresponding to the multiple grinding data sections, a number of the value increments that are greater than or equal to a fully-grinding threshold is defined as an achieving times value;
the stopping condition is that the achieving times value is greater than or equal to a setting times value;
when the processing unit determines that the achieving times value is greater than or equal to the setting times value, the processing unit controls the grinding base to stop grinding.

10. The control method for improving probe grinding efficiency as claimed in claim 9, wherein:
the probe card has multiple probes; the processing unit stores an average grinding value of the multiple probes, and the fully-grinding threshold is a product of a number of the multiple probes and the average grinding value.
